(19) United States
(12) Patent Application Publication
(10) Pub. No.: US 2019/0013326 A1
(43) Pub. Date: Jan. 10, 2019

(54) COMPOSITE SUBSTRATE OF THREE-DIMENSIONAL MEMORY DEVICES

(71) Applicant: Yangtze Memory Technologies Co., Ltd., Wuhan (CN)

(72) Inventors: Wenyu HUA, Wuhan (CN); Zhiliang XIA, Wuhan (CN); Yangbo JIANG, Wuhan (CN); Fandong LIU, Wuhan (CN); Peizhen HONG, Wuhan (CN); Fenghua FU, Wuhan (CN); Yaohua YANG, Wuhan (CN); Ming ZENG, Wuhan (CN); Zongliang HUO, Wuhan (CN)

(73) Assignee: Yangtze Memory Technologies Co., Ltd., Wuhan (CN)

(21) Appl. No.: 16/046,299

(22) Filed: Jul. 26, 2018

Related U.S. Application Data
(63) Continuation of application No. PCT/CN2018/077731, filed on Mar. 1, 2018.

(30) Foreign Application Priority Data
Mar. 7, 2017 (CN) 201710131749.3

(51) Int. Cl. H01L 27/11578; H01L 27/1157; H01L 29/792; H01L 29/66; H01L 21/28

(52) U.S. Cl. CPC H01L 27/11578; H01L 27/1157; H01L 21/28282; H01L 29/66833; H01L 29/792

(57) ABSTRACT

The present disclosure describes methods and structures for three-dimensional memory devices. The methods include providing a bottom substrate and forming a plurality of doped layers over the bottom substrate. The plurality of doped layers has a total thickness in a thickness range such that a top surface of the plurality of doped layers is substantially flat and a doping concentration of each of the plurality of doped layers is substantially uniform along a direction substantially perpendicular to the top surface of the plurality of doped layers.

### CROSS-REFERENCE TO RELATED APPLICATIONS

This application claims the priority of Chinese Patent Application No. 201710131749.3 filed on Mar. 7, 2017 and PCT Patent Application No. PCT/CN2018/077731 filed on Mar. 1, 2018, the entire content of which is incorporated herein by reference.

### BACKGROUND

Flash memory devices have undergone rapid development. Flash memory devices can store data for a considerably long time without powering, and have the advantages such as high integration level, fast access, easy erasing and rewriting, thus becoming the mainstream of non-volatile memory storage. Based on different structures, flash memory is divided into non-NAND flash memory (e.g., NOR flash memory) and NAND flash memory. Compared to NOR flash memory, NAND flash memory provides higher cell densities, higher storage densities, and faster write and erase operations.

With the development of planar flash memory, the semiconductor manufacturing process of flash memory has made great advances. However, the development of planar flash memory currently faces various challenges such as physical limits including exposure technology limits, development technology limits, and storage electron density limits. Accordingly, three-dimensional (3D) flash memory applications are being developed to address the challenges encountered by planar flash memory and to pursue lower production costs.

### BRIEF SUMMARY

The present disclosure provides methods of forming a flash memory device. The methods can improve the performance of the memory device.

To solve the aforementioned problem, the present disclosure provides a method for forming a memory device. The method includes: providing a bottom substrate, the bottom substrate having a control circuit thereon, and forming a top substrate over the control circuit. During the formation of the top substrate, an in-situ doping method can be used to dope dopants (e.g., conductive ions) into the top substrate. The top substrate can have an optimized thickness. The top substrate includes a first substrate layer and a second substrate layer over the first substrate layer. The dopant concentration of the first substrate layer is greater than the dopant concentration of the second substrate layer. The method further includes forming a memory cell circuit over the top substrate, the memory cell circuit and the control circuit being conductively connected.

In some embodiments, the optimized thickness is about 200 nm to about 1000 nm.

In some embodiments, the dopant concentration of first substrate layer is about 50 times to about 200 times of the dopant concentration of the second substrate layer.

In some embodiments, the dopant concentration of the first substrate layer is about 1E18 atoms/cm³ to about 2E18 atoms/cm³; and the dopant concentration of the second substrate layer is about 1E16 atoms/cm³ to about 3E16 atoms/cm³.

In some embodiments, when the memory cell circuit is N type, the dopants are P type, and when the memory cell circuit is P type, the dopants are N type.

In some embodiments, forming the top substrate includes: forming the first substrate layer over the control circuit, and doping the first substrate layer using an in-situ doping process; and forming the second substrate layer over the first substrate layer, and doping the second substrate layer using an in-situ doping process.

In some embodiments, forming the first substrate layer includes a first deposition process; and forming the second substrate layer includes a second deposition process.

In some embodiments, the first deposition process includes a low pressure chemical vapor deposition (LPCVD) process; and the second deposition process includes another LPCVD process.

In some embodiments, the first deposition process includes a first reactant gas and a first dopant source gas. The first dopant source gas includes a first diluent source gas and a first initial dopant source gas. The first initial dopant source gas includes a first intrinsic dopant source gas and a first intrinsic diluent source gas. The first reactant gas has a flow rate of about 30 standard cubic centimeters per minute (sccm) to about 100 sccm, the first dopant source gas has a flow rate of about 300 sccm to about 500 sccm, the chamber pressure is about 300 m Torr to about 500 m Torr, and the chamber temperature is about 500 degrees Celsius to about 550 degrees Celsius.

In some embodiments, the first reactant gas includes silane; the first diluent source gas includes nitrogen, the first intrinsic dopant source gas includes diborane, the first intrinsic diluent source gas includes nitrogen, and the first intrinsic dopant source gas has a molar ratio of 0.8% to 1.5% of the first initial dopant source gas.

In some embodiments, obtaining the first dopant source gas includes: providing the first initial dopant source gas and diluting the first initial dopant source gas with the first diluent source gas. The volume ratio of the first diluent source gas to the first initial dopant source gas is about 20:1 to about 50:1.

In some embodiments, the second deposition process includes a second reactant gas and a second dopant source gas. The second dopant source gas includes a second diluent source gas and a second initial dopant source gas. The second initial dopant source gas includes a second intrinsic dopant source gas and a second intrinsic diluent source gas. The second reactant gas has a flow rate of about 10 sccm to about 30 sccm, the second dopant source gas has a flow rate of about 2000 sccm to about 3000 sccm, the chamber pressure is about 300 m Torr to about 500 m Torr, and the chamber temperature is about 500 degrees Celsius to about 550 degrees Celsius.

In some embodiments, the second reactant gas includes disilane; the second diluent source gas includes nitrogen, the second intrinsic dopant source gas includes diborane, the second intrinsic diluent source gas includes nitrogen, and the second intrinsic dopant source gas has a molar ratio of 0.8% to 1.5% of the second initial dopant source gas.

In some embodiments, obtaining the second dopant source gas includes: providing the second initial dopant source gas and diluting the second initial dopant source gas with a second diluent source gas. The volume ratio of the second diluent source gas to the second initial dopant source gas is about 500:1 to about 1000:1.

In some embodiments, the memory cell circuit includes a 3D NAND memory cell circuit.

In some embodiments, forming the memory cell circuit includes: forming a dielectric stack over the top substrate; forming a plurality of through holes and channel holes through the dielectric stack; forming an epitaxial substrate layer at the bottom of the channel hole; and forming a channel layer in the channel hole after the formation of the epitaxial substrate layer. In some embodiments, forming the memory cell circuit further includes: forming a capping layer over the dielectric stack and the channel layer; forming a trench through the capping layer and the dielectric stack, the trench being located on one side of the channel hole; and forming a source-line doped region in the second substrate layer at the bottom of the trench.

In some embodiments, the dielectric stack includes a plurality of insulating layers and a plurality of sacrificial layers alternatingly stacking together, and the top layer and the bottom layer of the dielectric stack are insulating layers. In some embodiments, forming the memory cell circuit further includes: after the formation of the source-line doped region, removing the sacrificial layer to form a horizontal trench, and a control gate is formed in the horizontal trench. Further, after the formation of the control gate, forming a source line structure in the trench.

Compared with conventional technology, the technical solution of the present disclosure has at least the following advantages.

In the disclosed method, a top substrate is formed over a control circuit, and the top substrate is doped with dopants by an in-situ doping process during the formation of the top substrate. The top substrate includes a first substrate layer and a second substrate layer over the first substrate layer. Although the dopant concentration of the first substrate layer is greater than the dopant concentration of the second substrate layer, dopant diffusion from the first substrate layer to the second substrate layer is reduced because of in-situ doping. The dopant distribution in the second substrate layer is less affected by the dopant diffusion of the first substrate layer. The uniformity of the dopant distribution in the second substrate layer is improved. Further, dopants are doped in the second substrate layer by in-situ doping so that dopant distribution in the second substrate layer has improved uniformity. Thus, the electrical properties of memory cell circuits in various regions over the top substrate can have improved uniformity.

Further, during the formation of the top substrate, the top substrate is doped with dopants using an in-situ doping process. The control circuit is thus less susceptible to dopant diffusion from the first substrate layer. Accordingly, the electrical stability of the control circuit can be improved.

### BRIEF DESCRIPTION OF THE DRAWINGS

The accompanying drawings, which are incorporated herein and form a part of the specification, illustrate embodiments of the present disclosure and, together with the description, further serve to explain the principles of the present disclosure and to enable a person skilled in the pertinent art to make and use the present disclosure.

FIG. 1 is an illustration of a three-dimensional memory device.

FIGS. 2-5 are each an illustration of a cross-sectional view of a three-dimensional memory structure at different stages of an exemplary fabrication process, according to some embodiments.

FIG. 6 is an illustration of a fabrication process for forming a three-dimensional memory structure, according to some embodiments.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

As used herein, the term “3D memory device” refers to a semiconductor device with vertically oriented strings of memory cell transistors (referred to herein as “memory strings,” such as NAND strings) on a laterally-oriented substrate so that the memory strings extend in the vertical direction with respect to the substrate. As used herein, the term “vertical/vertically” means nominally perpendicular to the lateral surface of a substrate.

In flash memory manufacturing, more techniques have been applied to obtain cost/bit reduction by decreasing memory cell sizes and/or increasing the space occupied by memory cells. One technique is the periphery under cell (PUC) technology. According to this technique, periphery circuitry (e.g., control circuit) can be arranged under memory cells. This arrangement allows the dimensions of a flash memory device to be reduced and more space to be used for memory cell formation. This technique can thus further increase the memory capacity of the flash memory device and reduce the cost to manufacture the flash memory device.

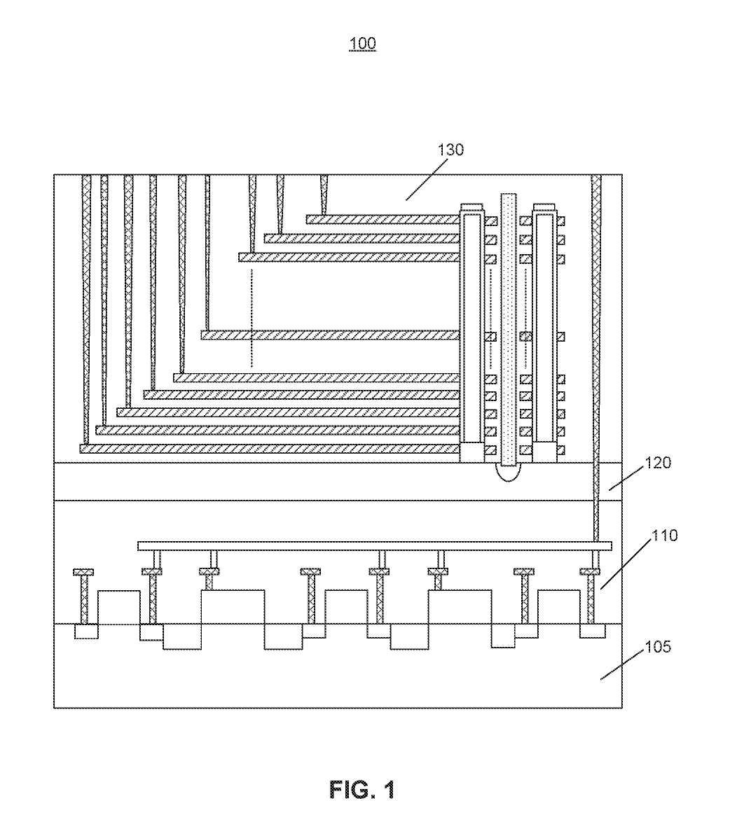

FIG. 1 illustrates a NAND flash memory structure 100 using PUC technology. As shown in FIG. 1, structure 100 includes a bottom substrate 105 and a top substrate 120 over bottom substrate 105. A control circuit 110 (e.g., including peripheral devices) is formed over bottom substrate 105. Top substrate 120 is doped with dopants and is over control circuit 110. A memory cell circuit 130 is formed over top substrate 120, which contains a plurality of memory cells. Memory cell circuit 130 and control circuit 110 are conductively connected. Often, top substrate 120 includes a first substrate layer over control circuit 110 and a second substrate layer over the first substrate layer. The dopant concentration of the first substrate layer is often higher than the dopant concentration of the second substrate layer. The first substrate layer and the second substrate layer can be formed respectively by ion implantation into two different depths along a direction substantially perpendicular to the top surface of top substrate 120. For example, a first ion implantation can be performed to dope a first depth of top substrate 120 to form the first substrate layer, and a second ion implantation can be performed to dope a second depth of top substrate 120 to form the second substrate layer. Memory cells are subsequently formed over top substrate 120. Semiconductor channels and source lines are formed in the top surface of top substrate 120 through an epitaxial substrate layers and source-line doped regions, respectively. The semiconductor channels and the source lines can be conductively connected to the top surface of top substrate 120 so that biases can be applied on the bottoms of semiconductor channels and source-line doped regions (e.g., in the second substrate layer) to control the operations (e.g., read, write, and erase) of memory cells.

Conventionally, ion implantation is used to dope both the first substrate layer and the second substrate layer of top substrate 120. The doping profiles in the first substrate layer and the second substrate layer can be Gaussian distribution. However, because of the difference in dopant concentration between the first substrate layer and the second substrate layer, dopants in the first substrate layer have a tendency to diffuse into the second substrate layer. As a result, dopants in the second substrate layer can form a doping profile (e.g., a layered distribution or an incremental distribution) different from the original Gaussian distribution. Accordingly, dopant concentration at the same depth can vary. Also, ion implantation can cause damages to top substrate 120. When the epitaxial substrate layers and the source-line doped regions are being formed, the top surface of top substrate 120 undergoes recess etches. Because of fabrication error/variation, different etch depths can be formed in top substrate 120. As a result of the non-uniformly distributed dopants in the second substrate layer, different dopant concentrations can be formed under different recesses, causing conductivity between the second substrate layer and different semiconductor channels/source lines to vary at different locations. This difference in conductivity can adversely affect the uniformity of the threshold voltages of memory cells of structure 100.

For example, because the source-line doped region is doped with dopant type (e.g., dopant polarity) opposite of the dopant type of the second substrate layer and the first substrate layer, dopant diffusion from the source-line doped region to the first substrate layer can neutralize a portion of the dopants in the first substrate layer and/or the second substrate layer, causing the dopant distribution to change. When a bias is applied on the second substrate layer to erase data in desired memory cells, voltage may not be evenly distributed on these memory cells. The data erasing function may be affected. Thus, conventional flash memory devices need to be improved.

The present disclosure describes a three-dimensional memory device having a PUC configuration. In the disclosed memory device, the memory cells are arranged over the control circuit, and top substrate (e.g., also referred to as the composite substrate) between the control circuit and the memory cells can be formed from low-pressure chemical vapor deposition (LPCVD) and can be doped through in-situ doping. Accordingly, dopant concentrations in the first substrate layer and the second substrate layer can have improved uniformity, and less defects/damages to the top substrate can be formed compared to the conventional ion implantation process. Thus, electrical connections between the second substrate layer and the structures formed at the top surface of the second substrate layer can be more uniform, and memory cells can have more uniform threshold voltages. Meanwhile, the thicknesses of the first substrate layer and the second substrate layer can be controlled such that dopant diffusion can be suppressed and the parasitic capacitance between the control circuit and the memory cells can be controlled. In addition, the aspect ratio of the subsequently-formed metal contact via between the memory cell circuit and the control circuit can be controlled to sufficiently low. It can be easier to form the metal contact via. By using the disclosed method and structure, device performance can be improved.

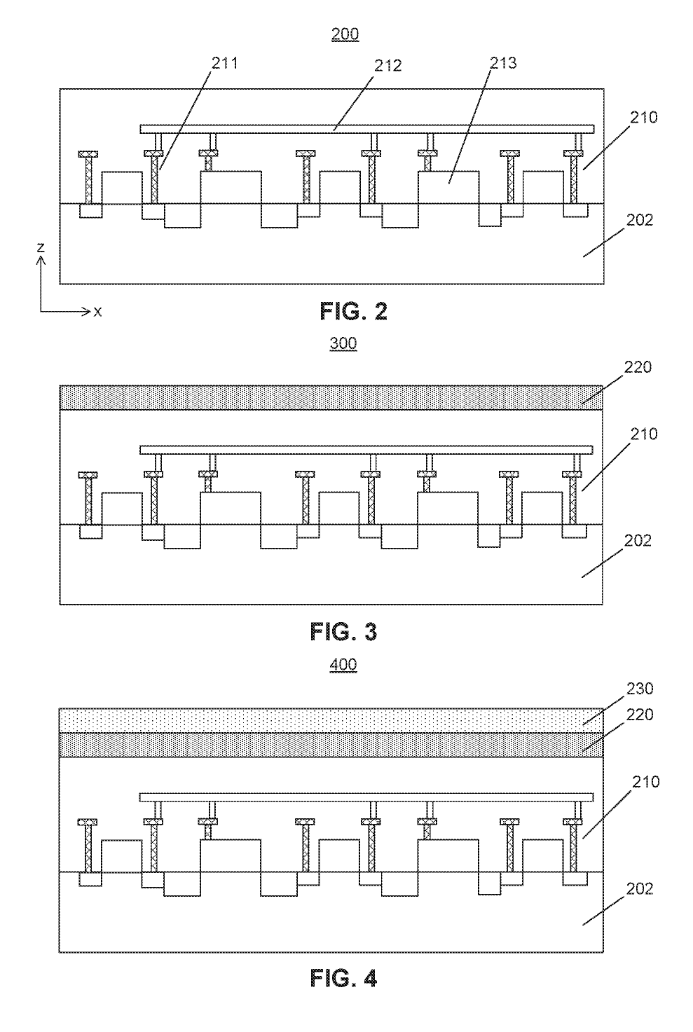

FIGS. 2-5 each illustrates a three-dimensional memory device in a different fabrication step, according to some embodiments. For illustrative purposes, similar or same parts in a three-dimensional memory device are labeled using the same element numbers. However, element numbers are merely used to distinguish relevant parts in the Detailed Description and do not indicate any similarity or difference in functionalities, compositions, or locations. Other parts of the memory device are not shown for ease of description. Although using a three-dimensional memory device as an example, in various applications and designs, the disclosed structure can also be applied in similar or different semiconductor devices to, e.g., improve the dopant uniformity between adjacent layers of different dopant concentrations and reduce the damages caused by ion implantation. The specific application of the disclosed structure should not be limited by the embodiments of the present disclosure.

FIG. 2 illustrates an exemplary structure 200 for forming a three-dimensional memory device, according to some embodiments. Structure 200 can include a bottom structure 202. Bottom substrate 202 can also be referred to as the base substrate, providing fabrication platform for the subsequently-formed top substrate and memory cells over the top substrate. In some embodiments, bottom substrate 202 includes any suitable material for forming the three-dimensional memory structure. For example, bottom substrate 202 can include silicon (e.g., single-crystalline silicon, poly silicon, and amorphous silicon), silicon germanium, silicon carbide, silicon on insulator (SOI), germanium on insulator (GOI), glass, gallium nitride, gallium arsenide, and/or other suitable III-V compound. In some embodiments, bottom substrate 202 includes single-crystalline silicon.

Bottom substrate 202 can include a control circuit 210 formed over a top surface of bottom substrate 202. For illustrative purposes, the semiconductor layer containing the control circuit is represented by element 210. Control circuit 210 can control the operation of the subsequently-formed memory cells and other related parts of the three-dimensional memory device. For example, control circuit 210 can generate control signals to control the operation of the subsequently-formed memory cells. Control circuit 210 can include any suitable electronic components such as transistors 213, contact vias 211, and metal interconnects 212. Other parts (e.g., resistors, capacitors, etc.) are not shown in FIG. 2. In some embodiments, subsequently-formed metal contact vias connecting the memory cells can be conductively connected to contact vias 211 and/or metal interconnects 212 such that control signals can be transmitted from control circuit 210 to the subsequently-formed memory cells.

FIG. 3 illustrates an exemplary structure 300 for forming a three-dimensional memory device. Structure 300 can include bottom substrate 202 and a first substrate layer 220 formed over control circuit 210. In some embodiments, structure 300 can be formed from structure 200 by depositing at least first substrate layer 220. First substrate layer 220 can have a desirably high dopant concentration and form a bottom portion of a subsequently-formed top substrate.

Optionally, an inter-layer dielectric layer (e.g., a passivation layer, not shown in FIG. 3) can be formed between control circuit 210 and first substrate layer 220. The inter-layer dielectric layer can provide electrical isolation between control circuit 210 and first substrate layer 220 so that dopant diffusion from first substrate layer 200 to control circuit 210 can be reduced/prevented. In some embodiments, the thickness of the inter-layer dielectric layer is associated with the parasitic capacitance between control circuit 210 and the subsequently-formed memory cell circuit. Accordingly, the thickness of the inter-layer dielectric layer cannot be overly small. Meanwhile, because a metal contact via, connecting control circuit 210 and subsequently-formed memory cell circuit, can be formed through the inter-layered dielectric layer, the thickness of inter-layer dielectric layer cannot be overly large such that the aspect ratio of the metal contact via is not significantly affected by the thickness of the inter-layer dielectric layer. In some embodiments, the thickness of the inter-layer dielectric layer can be in the range of about 100 nm to about 1000 nm.

The inter-layer dielectric layer can include any suitable dielectric materials and can be formed using any suitable deposition process. For example, the inter-layer dielectric layer can include silicon oxide (SiOₓ), silicon nitride (SiN), and/or silicon oxynitride (SiON), and can be formed by CVD, physical vapor deposition (PVD), plasma-enhanced CVD (PECVD), atomic layer deposition (ALD), and LPCVD. In some embodiments, the inter-layer dielectric layer includes silicon oxide and can be formed by LPCVD. Any suitable precursor gases (e.g., tetraethylorthosilicate and oxygen, triisopropylsilane and oxyten, and silane and oxygen) an/or oxidation of silicon can be used to form the silicon oxide. In some embodiments, the silicon oxide can be formed by the oxidation of silicon. Oxygen, optionally along with other carrier gases such as nitrogen, can be flown into the chamber to oxidize the top surface of control circuit 210. In some embodiments, the chamber (e.g., reaction) temperature for the oxidation process is about 385 degrees Celsius and the chamber pressure is about 1 Torr.

First substrate layer 220 can be formed over control circuit 210. In some embodiments, first substrate layer 220 is formed over the inter-layer dielectric layer. First substrate layer 220 can include doped polysilicon, doped amorphous silicon, and/or doped single-crystalline silicon and can be formed by any suitable deposition methods such CVD, PVD, PECVD, LPCVD, and/or ALD. In some embodiments, first substrate layer 220 includes amorphous silicon and is formed by LPCVD. In some embodiments, in-situ doping is performed during the growth of first substrate layer 220 to dope dopants of a desired type (e.g., N type or P type) into first substrate layer 220. In some embodiments, P type dopants such as boron (B), aluminum (Al), and/or gallium (Ga) are doped into first substrate layer 220. In some embodiments, the subsequently-formed memory cell circuit is N type, and boron is doped into first substrate layer 220. In some embodiments, the dopant concentration in first substrate layer 220 is in the range of about 1E18 atoms/cm³ to about 2E18 atoms/cm³.

Silane (SiH₄) can be the precursor gas in the LPCVD to form amorphous silicon of first substrate layer 220, and diborane (B₂H₆) can be the dopant source (e.g., boron) for the in-situ doping process such that boron can be uniformly doped into the formed amorphous silicon. In some embodiments, the thickness of first substrate layer 220 can have improved uniformity by using silane as the precursor gas. In some embodiments, silane is referred to as a first reactant gas, and diborane is referred to as a first intrinsic dopant source gas. In some embodiments, nitrogen can be used to dilute and carry the first intrinsic dopant source gas into the reaction chamber such that the first intrinsic dopant source gas can mix with the first reactant gas in a desirably short period of time. Accordingly, the formed boron-doped amorphous silicon first substrate layer 220 can have improved uniformity. Because the flow rate of the first intrinsic dopant source gas is much lower than the flow rate of the first reactant gas, in some embodiments, the first intrinsic dopant source gas is pre-mixed (e.g., mixed before the in-situ doping process) with a first intrinsic diluent source gas (e.g., N₂) to allow the first intrinsic dopant source gas to more uniformly mix with the first reactant gas during the in-situ doping process. In some embodiments, the mixture of the first intrinsic dopant source gas and the first intrinsic diluent source gas is referred to as a first initial dopant source gas, and a molar ratio of the first intrinsic dopant source gas to the first initial dopant source gas is in a range of about 0.8% to about 1.5%. In some embodiments, the ratio is about 1%. In some embodiments, the first initial dopant source gas is further pre-mixed with a first diluent source gas (e.g., N₂) before flown into the reaction chamber so that the first intrinsic dopant source gas can be further diluted and can have a more uniform distribution before mixing with the first reactant gas. In some embodiments, the mixture of the first diluent source gas and the first initial dopant source gas is referred to as a first dopant source gas, and the volume ratio of the first diluent source gas to the first initial dopant source gas is in the range of about 20:1 to about 50:1.

The first dopant source gas (e.g., containing the diluted first intrinsic dopant source gas) can be mixed with the first reactant gas in the reaction chamber to perform the LPCVD and in-situ doping process. Because the first intrinsic dopant source gas is diluted by the first intrinsic diluent source gas and the first diluent source gas before flown into the chamber, the first intrinsic dopant source gas is more uniformly distributed in the first dopant source gas, and the amount of first intrinsic dopant source gas can be more precisely detected/controlled. When flown into the chamber, gas atoms of the first dopant source gas can uniformly occupy the chamber in a desirably short time, further allowing the first intrinsic dopant source gas to distribute in the chamber in a desirably short time. Accordingly, the dopants in the first substrate layer can be more uniformly distributed and the dopant concentration of the first substrate layer can be more precisely controlled. In some embodiments, the flow rate of the first reactant gas is in the range of about 30 to about 100 sccm, the flow rate of the first dopant source gas is in the range of about 300 to about 500 sccm, the chamber pressure is in the range of about 300 to about 500 mTorr, and the chamber temperature is in the range of about 500 to about 550 degrees Celsius. In some embodiments, the first intrinsic dopant source gas can also be flown into the reaction chamber directly, or pre-mixed with the diluent gas at another ratio.

FIG. 4 illustrates an exemplary structure 400 for forming a three-dimensional memory device, according to some embodiments. Structure 400 may include bottom substrate 202, a first substrate layer 220 formed over control circuit 210, and a second substrate layer 230 formed over first substrate layer 220. First substrate layer 220 and second substrate layer 230 can form the top substrate (e.g., composite substrate), where first substrate layer 220 can be the lower portion of the top substrate along the z-axis (e.g., the direction perpendicular to the top surface of bottom substrate 202) and second substrate layer 230 can be the upper portion of the top substrate along the z-axis. In some embodiments, structure 400 can be formed from structure 300 by depositing second substrate layer 230. The dopant concentration of second substrate layer 230 can be lower than the dopant concentration of first substrate layer 220. Second substrate layer 230 can provide a base for the subsequent formation of memory cells and memory cell circuit. Second substrate layer 230 can include doped polysilicon, doped amorphous silicon, and/or doped single-crystalline silicon and can be formed by any suitable deposition methods such CVD, PVD, PECVD, LPCVD, and/or ALD. In some embodiments, second substrate layer 230 includes doped amorphous silicon and is formed by LPCVD. In some embodiments, in-situ doping is performed during the growth of second substrate layer 230 to dope dopants of the same type (e.g., N type or P type) as first substrate layer 220. In some embodiments, P type dopants such as boron (B), aluminum (Al), and/or gallium (Ga) are doped into second substrate layer 230. In some embodiments, the subsequently-formed memory cell circuit is N type, and boron is doped into second substrate layer 230.

The dopant concentration of first substrate layer 220 can be about 50 to about 200 times the dopant concentration of second substrate layer 230. In some embodiments, the dopant concentration of second substrate layer 230 is in the range of about 1E16 atoms/cm³ to about 3E16 atoms/cm³.

Disilane (Si₂H₆) can be the precursor gas in the LPCVD to form amorphous silicon in second substrate layer 230, and diborane (B₂H₆) can provide boron dopants for the in-situ doping process such that boron can be uniformly doped into the formed amorphous silicon. In some embodiments, disilane is referred to as a second reactant gas, and diborane is referred to as a second intrinsic dopant source gas. In some embodiments, nitrogen can be used to dilute and carry the second intrinsic dopant source gas into the reaction chamber such that the second intrinsic dopant source gas can mix with the second reactant gas in a desirably short period time. Accordingly, the formed boron-doped amorphous silicon second substrate layer 230 can have improved uniformity. Because the flow rate of the second intrinsic dopant source gas is much lower than the flow rate of the second reactant gas, in some embodiments, the second intrinsic dopant source gas is pre-mixed (e.g., mixed before the in-situ doping process) with a second intrinsic diluent source gas (e.g., N₂) to allow the second intrinsic dopant source gas to more uniformly mix with the second reactant gas during the in-situ doping process. In some embodiments, the mixture of the second intrinsic dopant source gas and the second intrinsic diluent source gas is referred to as a second initial dopant source gas, and a molar ratio of the second intrinsic dopant source gas to the second initial dopant source gas is in a range of about 0.8% to about 1.5%. In some embodiments, the ratio is about 1%. In some embodiments, the second initial dopant source gas is further pre-mixed with a second diluent source gas (e.g., N₂) before flown into the reaction chamber so that the second intrinsic dopant source gas can be further diluted and can have a more uniform distribution before mixing with the second reactant gas. In some embodiments, the mixture of the second diluent source gas and the second initial dopant source gas is referred to as a second dopant source gas, and the volume ratio of the second diluent source gas to the second initial dopant source gas is in the range of about 500:1 to about 1000:1. In some embodiments, the second intrinsic dopant source gas can also be flown into the reaction chamber directly, or pre-mixed with the diluent gas at another ratio.

The reasons to dilute the second intrinsic dopant source gas can be similar to the reasons to dilute the first intrinsic dopant source gas and are not repeated herein. In some embodiments, the flow rate of the second reactant gas is in the range of about 10 to about 30 sccm, the flow rate of the second dopant source gas is in the range of about 2000 to about 3000 sccm, the chamber pressure is in the range of about 300 to about 500 mTorr, and the chamber temperature is in the range of about 500 to about 550 degrees Celsius.

Forming first substrate layer 220 and second substrate layer 230 using LPCVD and in-situ doping, the formed first substrate layer 220 and second substrate layer 230 can have better film quality (e.g., being less susceptible to pit holes or damages resulted from ion implantation) and more uniform thicknesses. By diluting the intrinsic dopant source gases before flowing them into the reaction chamber, the small amount of intrinsic dopant source gases can be easier to measure and the intrinsic dopant source gases can distribute in the reaction chamber more uniformly. The dopants formed into each of first substrate layer 220 and second substrate layer 230 can be more uniformly distributed and the dopant concentrations can be easier to control. In some embodiments, the dopant distributions in first substrate layer 220 and second substrate layer 230 are substantially uniform (e.g., along the z-axis).

Further, dopants in each of first substrate layer 220 and second substrate layer 230 can form a substantially uniform doping profile (e.g., substantially the same doping level) along the z-axis such that dopant in each of first substrate layer 220 and second substrate layer 230 are less susceptible to diffusion along the z-axis. In addition, the dopant concentration of the first substrate layer 220 is about 50 to about 200 times the dopant concentration of second substrate layer 230. The reasons for the range can include the follows. The dopant concentration of first substrate layer 220 can be sufficiently higher than the dopant concentration of second substrate layer 230 to reduce/eliminate the impact caused by the dopant diffusion from the source-line doped region, as described previously. However, an overly high dopant concentration (e.g., higher than 200 times) of first substrate layer 220 can increase dopant diffusion from first substrate layer 220 to second substrate layer 230, causing potential non-uniform distribution of dopants (e.g., non-uniform dopant concentration) in first substrate layer 220. The non-uniform distribution of dopants can further cause the threshold voltage variation in the subsequently-formed memory cells. Doping can be more costly when the dopant concentration increases. Further, an overly low dopant concentration (e.g., lower than 50 times) of first substrate layer 220 may not provide sufficient dopants in a unit volume, and is susceptible to change of dopant type in first substrate layer 220 due to dopant neutralization caused by the subsequently-formed source-line doped region. Thus, an optimized range (e.g., about 50 times to about 200 times the dopant concentration of second substrate layer 230) of dopant concentrations of first substrate layer 220 can improve the threshold voltage uniformity of the memory cells, reduce the susceptibility of dopant type change, and the fabrication process can be less costly.

Further, first substrate layer 220 and second substrate layer 230 can together have an optimized thickness range. The reasons for the optimized thickness range can include the follows. An overly thick first substrate layer 220 or second substrate layer 230 can cause dopant diffusion within each substrate and/or between first substrate layer 220 and second substrate layer 230. Also, as first substrate layer 220 becomes thicker, the thickness of first substrate layer 220 can become less uniform and the top surface of first substrate layer 220 can be more susceptible to unevenness. As a result, the top surface of second substrate layer 230 can be more susceptible to unevenness, affecting the memory cells subsequently formed over second substrate layer 230. Meanwhile, an overly thin first substrate layer 220 or second substrate layer 230 can be difficult to form using LPCVD due to the precise control of parameters of the deposition processes. Thus, an optimized thickness range of first substrate layer 220 and second substrate layer 230 can together be about 200 nm to about 1000 nm. In some embodiments, the total thickness of first substrate layer 220 and second substrate layer 230 can be about 300 nm.

By using the disclosed method to form first substrate layer 220 and second substrate layer 230, a doping profile with improved uniformity can be formed in each of first substrate layer 220 and second substrate layer 230. By controlling the dopant concentrations and thicknesses of first substrate layer 220 and second substrate layer 230, dopant diffusion (e.g., along the z-axis) can be reduced/suppressed, and the dopant concentration at the top surface of second substrate layer 230 can be more uniform, allowing structures (e.g., memory cells, semiconductor channel holes, and gate line slit trenches) subsequently formed over second substrate layer 230 can have more uniform conductivity. By controlling the thicknesses of first substrate layer 220 and second substrate layer 230, a fabrication base with improved evenness/flatness can be provided for the fabrication of memory cells, and diffusion between first substrate layer 220 and second substrate layer 230 can be further suppressed. The disclosed method thus allows first substrate layer 220 to have a more uniform dopant concentration in first substrate layer 220, and the memory cells can have more uniform threshold voltages. Further, the dopant diffusion in first substrate layer 220 towards control circuit 210 can be reduced/suppressed, leakage current between first substrate layer 220 and control circuit 210 can be reduced, and control circuit 210 can have improved electrical stability.

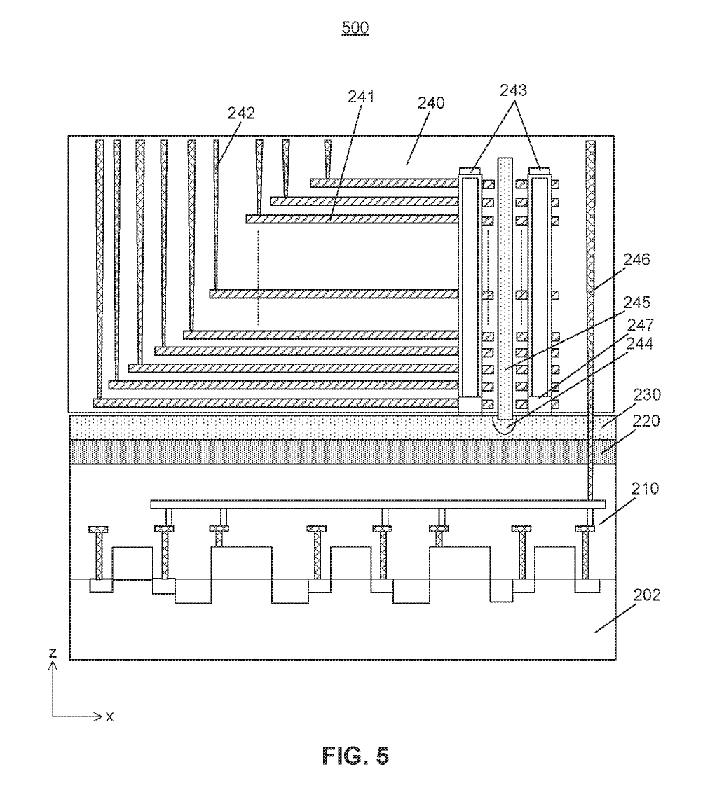

FIG. 5 illustrates an exemplary structure 500 for forming a three-dimensional memory device, according to some embodiments. Structure 500 can include control circuit 210, first substrate layer 220 over control circuit 210, second substrate layer 230 over first substrate layer 220, and a memory cell circuit 240 over second substrate layer 230. Memory cell circuit 240 can receive control signals from control circuit 210 and perform various functions such as read, write, and/or erase. In some embodiments, structure 500 can be formed from structure 400 after forming memory cell circuit 240 over second substrate layer 230.

In some embodiments, memory cell circuit 240 includes a three-dimensional NAND memory cell circuit. As shown in FIG. 5, memory cell circuit 240 can include a memory stack 241 having a plurality of alternating conductor/dielectric layers, contact vias 242 conductively connect the gate electrodes (e.g., conductor) with bit lines, semiconductor channels 243, and a source line 245 formed in a source-lined doped region 244. Memory cell circuit 240 can be conductively connected to control circuit 210 through a metal contact via 246.

The formation of memory cell circuit 240 (e.g., elements 241-245) can be formed using any suitable methods. For example, an alternating dielectric stack (e.g., a material layer) can be formed over second substrate layer 230. The dielectric stack can include a plurality of alternating insulating layers (e.g., silicon oxide layers) and a plurality of sacrificial layers (e.g., silicon nitride layers). The top layer and the bottom layer of the dielectric stack can be an insulating layer. A plurality of channel holes can be formed through the dielectric stack, and any suitable materials can be filled in the channel holes to form semiconductor channels. Further, a capping layer (e.g., including a suitable dielectric material such as silicon oxide) for preventing leakage current of subsequently-formed gate electrodes and bitlines can be formed over the dielectric stack and the semiconductor channels, and the dielectric stack can be patterned (e.g., using any suitable patterning operations such as photolithography and a follow-up etch) to form one or more vertical trenches extending along the x-axis. The vertical trenches can be through the dielectric stack and the capping layer, separating arrays of semiconductor channels. Source-line doped region 244 can be formed at the bottom (e.g., in second substrate layer 230) of a vertical trench by, for example, ion implantation. A suitable dielectric material such as silicon oxide can be deposited on the sidewalls of the vertical trenches to form gate line slits. Further, an opening in gate line slit can be formed and source line 245 can be formed by filling a suitable conductive material in the opening/center of the gate line slit. In some embodiments, dopants of source-line doped region 244 has an opposite dopant type than the dopants in first substrate layer 220 and second substrate layer 230. In some embodiments, dopants of source-line doped region 244 includes N-type dopants, such as phosphoric (P), arsenic (As), and/or antimony (Sb).

In some embodiments, forming the semiconductor channels includes forming an epitaxial substrate layer 247 at the bottom of a channel hole before filling the channel hole with other materials. The epitaxial substrate layer 247 can be doped with dopants of the same dopant type (e.g., P type) as dopants in first substrate layer 220 and second substrate layer 230. In some embodiments, a gate dielectric layer is formed on the sidewall of a channel hole, and a semiconductor channel layer is formed over the gate dielectric layer. In some embodiments, the capping layer covers the gate dielectric layer. In some embodiments, a channel dielectric layer is formed in the channel hole and is surrounded by the semiconductor channel layer. In some embodiments, the capping layer covers the gate dielectric layer and the channel dielectric layer.

In some embodiments, after source-line doped region 244 is formed, sacrificial layers in the dielectric stack are removed to form horizontal trenches. A suitable conductive material (e.g., tungsten) can be deposited to fill in the horizontal trenches and form control gate electrodes. After the control gates are formed, source line 245 can be formed in the gate line slit. In some embodiments, a gate dielectric layer is deposited in the horizontal trenches before the deposition of the conductive material. In some embodiments, a dielectric fill material, e.g., silicon oxide, can be deposited to insulate parts of memory cell circuit 240.

In some embodiments, a plurality of bit line scan be formed over the control gate electrodes. The bit lines can extend in a direction perpendicular to the x-z plane. In some embodiments, a plurality of contact vias can be formed on the control gate electrodes. The contact vias can be through the dielectric fill material and connecting the control gate electrodes with the bit lines for signal transmission between the control gate electrodes and the bit lines.

In some embodiments, a metal contact via can be formed through the dielectric fill material of memory circuit 240, second substrate layer 230, first substrate layer 220, and the dielectric fill material in control circuit 210 to conductively connect metal cell circuit 240 and control circuit 210. In some embodiments, a contact hole can be formed through memory cell circuit 240, second substrate layer 230, first substrate layer 220, and a portion of the dielectric fill material of control circuit 210, and a suitable conductive material can be used to fill in the contact hole. The contact hole can be formed by any suitable patterning process, e.g., a photolithography process and a follow-up etch. In some embodiments, the etch includes a dry etch and/or a wet etch. The conductive material can include any suitable conductive material such as copper, aluminum, and/or tungsten.

Using the disclosed method and structure, dopant concentration of second substrate layer 230 has improved uniformity along the z-axis and at the top surface. When second substrate layer 230 is etched to form structures such as source-line doped regions 244, because the dopant concentration has improved uniformity at the top surface of second substrate layer 230, the exposed portions of the top surface of second substrate layer 230 can have substantially same/uniform dopant concentrations. Accordingly, source-line doped regions 244, formed at different locations over second substrate layer 230, can be formed over portions of second substrate layer 230 with substantially the same dopant concentrations. Variation of etch depth due to fabrication error can thus cause less variation in dopant concentration under source-line doped regions 244. Dopant diffusion and neutralization between dopants in source-line doped regions 244 and first substrate layer 220 can be reduced.

Further, during the formation of semiconductor channels 243, an epitaxial substrate layer 247 can be formed at the bottom of a channel hole before the deposition of other materials in the channel hole. As described above, the dopant concentration has improved uniformity at the top surface of second substrate layer 230. Because the epitaxial substrate layer 247 is formed over an etched portion of the top surface of second substrate layer 230, dopant concentration under each epitaxial substrate can be substantially the same. Variation of etch depth due to fabrication error can thus cause less variation in dopant concentration under the epitaxial substrate layer 247. Accordingly, diffusion between dopants of epitaxial substrate layers 247 and second substrate layer 230 can result in substantially uniform dopant distribution under each semiconductor channel 243. Thus, the threshold voltages of the memory cells associated with each semiconductor channel 243 can be substantially the same.

In some embodiments, more than two substrates (e.g., doped layers) are formed in the composite substrate over control unit 210 using the disclosed method. The more than two substrates can each have a uniform dopant concentration and an optimized thickness range. In some embodiments, the dopant concentration of each substrate decreases along the z-axis towards the subsequently-formed memory cell circuit. The specific number of substrates, dopant concentrations, and thickness ranges are dependent on different applications/embodiments and should not be limited by the embodiments of the present disclosure.

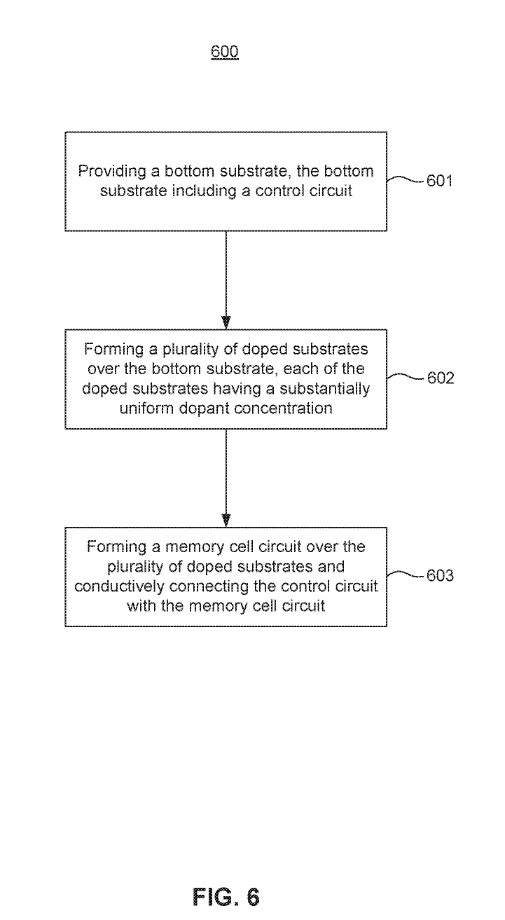

FIG. 6 is an illustration of an exemplary method 600 for forming a three-dimensional memory device, according to some embodiments. For explanation purposes, the operations shown in method 600 are described in context of FIGS. 2-5. In various embodiments of the present disclosure, the operations of method 600 can be performed in a different order and/or vary.

In operation 601, a bottom substrate is provided. A control circuit can be over the bottom circuit. The bottom substrate can also be referred to as the base substrate, providing fabrication platform for the subsequently-formed top substrate and memory cells over the top substrate. In some embodiments, bottom substrate includes any suitable material for forming the three-dimensional memory structure. For example, the bottom substrate can include silicon (e.g., single-crystalline silicon, poly silicon, and amorphous silicon), silicon germanium, silicon carbide, silicon on insulator (SOI), germanium on insulator (GOI), glass, gallium nitride, gallium arsenide, and/or other suitable III-V compound. In some embodiments, the bottom substrate includes single-crystalline silicon.

In some embodiments, the control circuit controls the operation of the subsequently-formed memory cells and other related parts of the three-dimensional memory device. The control circuit can include any suitable electronic components such as transistors, contact vias, and metal interconnects. Details description of the bottom substrate and the control circuit can be referred to the description of FIG. 2.

In operation 602, a plurality of doped substrates can be formed over the bottom substrate. Each of the plurality of doped substrates can have a substantially uniform dopant concentration. The plurality of doped substrates can stack on one another and form a composite substrate. In some embodiments, each of the doped substrates is formed using the disclosed LPCVD and in-situ doping process described in FIGS. 3 and 4. In some embodiments, the dopant concentration of the doped substrates decreases along the z-axis towards away from the top surface of the bottom substrate. In some embodiments, the thickness of each doped substrate and the total thickness of the composite substrate are each controlled within an optimized thickness range to improve the uniformity of dopant concentration. In some embodiments, the dopant concentration of each doped substrate is controlled within an optimized dopant concentration range to, e.g., suppress dopant diffusion between adjacent doped substrates and ensure proper dopant type in each doped substrate. In some embodiments, a first substrate layer is formed over the control circuit and a second substrate layer is formed over the first circuit. The dopant concentration of the first substrate layer can be about 50 to about 200 times the dopant concentration of the second substrate layer. In some embodiments, the dopant concentration of the first substrate layer is about 1E18 atoms/cm³ to about 2E18 atoms/cm³, and the dopant concentration of the second substrate layer is about 1E16 atoms/cm³ to about 3E16 atoms/cm³. In some embodiments, the total thickness of the first substrate layer and the second substrate layer can be about 200 nm to about 1000 nm. Detail description of the formation of doped substrates can be referred to the description of FIGS. 3 and 4.

In some embodiments, an inter-layer dielectric layer (e.g., a passivation layer) can be formed between the control circuit and the composite substrate. The inter-layer dielectric layer can provide electrical isolation between control circuit and the composite substrate so that dopant diffusion from composite substrate to the control circuit can be reduced/prevented. In some embodiments, the thickness of the inter-layer dielectric layer is associated with the parasitic capacitance between control circuit and the subsequently-formed memory cell circuit, and can be controlled within an optimized thickness range. In some embodiments, the thickness of the inter-layer dielectric layer can be in the range of about 100 nm to about 1000 nm. In some embodiments, the inter-layer dielectric layer includes silicon oxide and can be formed by LPCVD.

In some embodiments, the doped substrates of the composite substrate and the inter-layer dielectric layer can be formed in a same reaction chamber (e.g., furnace) using LPCVD. In some embodiments, the inter-layer dielectric layer can be formed under the same temperature range, e.g., about 300 to about 400 degrees Celsius. In some embodiments, the inter-layer dielectric layer can be formed under substantially the same temperature, e.g., about 385 degrees Celsius. Further, the chamber temperature can be changed to form the doped substrates in the composite substrate. In some embodiments, the first substrate layer and the second substrate layer can be formed under the same temperature range, e.g., about 500 to about 550 degrees Celsius. In some embodiments, the first substrate layer and the second substrate layer can be formed under substantially the same temperature, e.g., about 532 degree Celsius. Using the disclosed deposition methods, different layers can sequentially be formed in the same chamber, the formed structure is less susceptible to contamination, the fabrication process is simplified, and the formed films can thus have improved quality.

In operation 603, a memory cell circuit is formed over the plurality of doped substrates, and the control circuit is conductively connected to the memory cell circuit. The memory cell circuit. The memory cell circuit can receive control signals from the control circuit and perform various functions such as read, write, and/or erase. In some embodiments, the memory cell circuit includes a three-dimensional NAND memory cell circuit. For example, the memory cell circuit can include a memory stack having a plurality of alternating conductor/dielectric layers, contact vias conductively connect the gate electrodes (e.g., conductor) with bit lines, semiconductor channels, and source lines formed in source-lined doped regions. The memory cell circuit can be formed using any suitable methods. In some embodiments, the memory cell circuit is then conductively connected to the control circuit through a metal contact via. The metal contact via can be formed through any suitable methods such as patterning the memory cell circuit to form a contact hoe through the memory cell circuit, the composite substrate, and the control unit. A suitable conductive metal can be filled into the contact hole to form the metal contact via. Detail description of the formation of the memory cell circuit can be referred to the description of FIG. 5.

The present disclosure describes a three-dimensional memory device having a PUC configuration. In the disclosed memory device, the memory cells are arranged over the control circuit, and top substrate (e.g., also referred to as the composite substrate) between the control circuit and the memory cells can be formed from low-pressure chemical vapor deposition (LPCVD) and can be doped through in-situ doping. Accordingly, dopant concentrations in the first substrate layer and the second substrate layer can have improved uniformity, and less defects/damages to the top substrate can be formed compared to the conventional ion implantation process. Thus, electrical connections between the second substrate layer and the structures formed at the top surface of the second substrate layer can be more uniform, and memory cells can have more uniform threshold voltages. Meanwhile, the thicknesses of the first substrate layer and the second substrate layer can be controlled such that dopant diffusion can be suppressed and the parasitic capacitance between the control circuit and the memory cells can be controlled. In addition, the aspect ratio of the subsequently-formed metal contact via between the memory cell circuit and the control circuit can be controlled to sufficiently low. It can be easier to form the metal contact via. By using the disclosed method and structure, device performance can be improved.

In some embodiments, a method includes providing a bottom substrate and forming a plurality of doped layers over the bottom substrate. The plurality of doped layers has a total thickness in a thickness range such that a top surface of the plurality of doped layers is substantially flat and a doping concentration of each of the plurality of doped layers is substantially uniform along a direction substantially perpendicular to the top surface of the plurality of doped layers.

In some embodiments, a method includes: providing a bottom substrate, the bottom substrate including a control circuit; forming a plurality of doped layers over the bottom substrate; and forming a memory cell circuit over the plurality of doped layers. In some embodiments, the method further includes conductively connecting the control circuit and the memory cell circuit. The plurality of doped layers has a total thickness in a thickness range such that a top surface of the plurality of doped layers is substantially flat and a doping concentration in each of the plurality of doped layers is substantially uniform along a direction substantially perpendicular to the top surface of the plurality of doped layers.

In some embodiments, a three-dimensional memory includes: a bottom substrate; a control circuit over the bottom substrate; and a plurality of doped layers over the bottom substrate. The memory further includes a memory cell circuit over the plurality of doped layers; and a metal contact via conductively connecting the control circuit and the memory cell circuit. The plurality of doped layers has a total thickness in a thickness range such that a top surface of the plurality of doped layers is substantially flat and a doping concentration in each of the plurality of doped layers is substantially uniform along a direction substantially perpendicular to the top surface of the plurality of doped layers.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Embodiments of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections may set forth one or more but not all exemplary embodiments of the present disclosure as contemplated by the inventor(s), and thus, are not intended to limit the present disclosure and the appended claims in any way.

The breadth and scope of the present disclosure should not be limited by any of the above-described exemplary embodiments, but should be defined only in accordance with the following claims and their equivalents.

What is claimed is:

1. A method for forming a substrate in a memory, comprising:
providing a bottom substrate; and
forming a plurality of doped layers over the bottom substrate, wherein:
the plurality of doped layers has a total thickness in a thickness range such that a top surface of the plurality of doped layers is substantially flat and a doping concentration of each of the plurality of doped layers is substantially uniform along a direction substantially perpendicular to the top surface of the plurality of doped layers.

2. The method of claim 1, wherein
a dopant polarity of the each of the plurality of doped layers is the same; and
the doping concentration of one of the plurality of doped layers is lower than a lower adjacent one of the plurality of doped layers along the direction substantially perpendicular to the top surface of the plurality of doped layers.

3. The method of claim 2, wherein forming the plurality of doped layers comprises forming a first doped layer over the substrate and a second doped layer over the first doped layer, and wherein the doping concentration of the first doped layer is higher than the doping concentration of the second doped layer.

4. The method of claim 3, wherein:
the doping concentration of the first doped layer is about 50 to about 200 times of the doping concentration of the second doped layer;
the doping concentration of the first doped layer is in a range of about 1E18 atoms/cm³ to about 2E18 atoms/cm³; and the doping concentration of the second doped layer is in a range of about 1E16 atoms/cm³ to about 3E16 atoms/cm³; and
the thickness range is about 200 nm to about 1000 nm.

5. The method of claim 4, wherein a formation of at least one of the plurality of doped layers comprises one or more of in-situ doping and low-pressure chemical vapor deposition (LPCVD).

6. The method of claim 5, wherein
the plurality of doped layers comprises a first doped layer and a second doped layer; and
the first doped layer comprises a first boron-doped silicon layer and is formed through a first LPCVD and a first in-situ doping, and the second doped layer comprises a second boron-doped silicon layer and is formed through a second LPCVD and a second in-situ doping.

7. The method of claim 6, wherein:
the first LPCVD and the first in-situ doping comprise providing a first reactant gas for forming a first silicon layer and providing a first dopant source gas for in-situ doping the first silicon layer and form the first boron-doped silicon layer, wherein the first reactant gas comprises SiH₄ and the first dopant source gas comprises B₂H₆, and wherein in the first LPCVD and the first in-situ doping:
providing the first dopant source gas comprises: providing a first initial dopant source gas comprising B₂H₆; providing a first diluent source gas to dilute the first initial dopant source gas, wherein a volume ratio of the first diluent source gas to the first initial dopant source gas is in a range of about 20:1 to about 50:1, the first diluent source gas comprises N₂, the first initial dopant source gas comprises a first intrinsic dopant source gas comprising B₂H₆ and a first intrinsic diluting source gas comprising N₂, and a molar ratio of the first intrinsic diluting source gas is about 8% to about 1.5% of the first initial dopant source gas; and
the first dopant source gas has a flow rate of about 300 stand cubic centimeter per minute (sccm) to about 500 sccm, the first reactant gas has a flow rate of about 30 sccm to about 100 sccm, a chamber pressure is about 300 mTorr to about 500 mTorr, and a reaction temperature is about 500 degrees Celsius to about 550 degrees Celsius; and
the second LPCVD and the second in-situ doping comprise providing a second reactant gas for forming a second silicon layer and providing a second dopant source gas for in-situ doping the second silicon layer and form the second boron-doped silicon layer, wherein the second reactant gas comprises Si₂H₆ and the second dopant source gas comprises B₂H₆ and wherein in the second LPCVD and the second in-situ doping:
providing the second dopant source gas comprises: providing a second initial dopant source gas comprising B₂H₆; providing a second diluent source gas to dilute the first initial dopant source gas, wherein a volume ratio of the second diluent source gas to the second initial dopant source gas is in a range of about 500:1 to about 1000:1, the second diluent source gas comprises N₂, the second initial dopant source gas comprises a second intrinsic dopant source gas comprising B₂H₆ and a second intrinsic diluting source gas comprising N₂, and a molar ratio of the second intrinsic diluting source gas is about 8% to about 1.5% of the second initial dopant source gas; and
the second dopant source gas has a flow rate of about 2000 sccm to about 3000 sccm, the second reactant gas has a flow rate of about 10 sccm to about 300 sccm, a chamber pressure is about 300 mTorr to about 500 mTorr, and a reaction temperature is about 500 degrees Celsius to about 550 degrees Celsius.

8. A method for forming a three dimensional memory, comprising:
providing a bottom substrate, the bottom substrate comprising a control circuit;
forming a plurality of doped layers over the bottom substrate;
forming a memory cell circuit over the plurality of doped layers; and
conductively connecting the control circuit and the memory cell circuit, wherein:
the plurality of doped layers has a total thickness in a thickness range such that a top surface of the plurality of doped layers is substantially flat and a doping concentration in each of the plurality of doped layers is substantially uniform along a direction substantially perpendicular to the top surface of the plurality of doped layers.

9. The method of claim 8, wherein:
a dopant polarity of the each of the plurality of doped layers is the same; and
the doping concentration of one of the plurality of doped layers is lower than a lower adjacent one of the plurality of doped layers along the direction substantially perpendicular to the top surface of the plurality of doped layers.

10. The method of claim 9, wherein forming the plurality of doped layers comprises forming a first doped layer over the substrate and a second doped layer over the first doped layer, and wherein a doping concentration of the first doped layer is higher than a doping concentration of the second doped layer.

11. The method of claim 10, wherein:
the doping concentration of the first doped layer is about 50 to about 200 times of the doping concentration of the second doped layer;
the doping concentration of the first doped layer is in a range of about 1E18 atoms/cm³ to about 2E18 atoms/cm³; and the doping concentration of the second doped layer is in a range of about 1E16 atoms/cm³ to about 3E16 atoms/cm³; and
the thickness range is about 200 nm to about 1000 nm.

12. The method of claim 11, wherein a formation of at least one of the plurality of doped layers comprises at least one of in-situ doping and low-pressure chemical vapor deposition (LPCVD).

13. The method of claim 12, wherein
the plurality of doped layers comprises a first doped layer and a second doped layer; and
the first doped layer comprises a first boron-doped silicon layer and is formed through a first LPCVD and a first in-situ doping, and the second doped layer comprises a second boron-doped silicon layer is formed through a second LPCVD and a second in-situ doping.

14. The method of claim 13, wherein:
the first LPCVD and the first in-situ doping comprise providing a first reactant gas for forming a first silicon layer and providing a first dopant source gas for in-situ doping the first silicon layer and form the first boron-doped silicon layer, wherein the first reactant gas comprises SiH₄ and the first dopant source gas comprises B₂H₆ and wherein in the first LPCVD and the first in-situ doping:
providing the first dopant source gas comprises: providing a first initial dopant source gas comprising B₂H₆; providing a first diluent source gas to dilute the first initial dopant source gas, wherein a volume ratio of the first diluent source gas to the first initial dopant source gas is in a range of about 20:1 to about 50:1, the first diluent source gas comprises N₂, the first initial dopant source gas comprises a first intrinsic dopant source gas comprising B₂H₆ and a first intrinsic diluting source gas comprising N₂, and a molar ratio of the first intrinsic diluting source gas is about 8% to about 1.5% of the first initial dopant source gas; and
the first dopant source gas has a flow rate of about 300 stand cubic centimeter per minute (sccm) to about 500 sccm, the first reactant gas has a flow rate of about 30 sccm to about 100 sccm, a chamber pressure is about 300 mTorr to about 500 mTorr, and a reaction temperature is about 500 degrees Celsius to about 550 degrees Celsius; and
the second LPCVD and the second in-situ doping comprise providing a second reactant gas for forming a second silicon layer and providing a second dopant source gas for in-situ doping the second silicon layer and form the second boron-doped silicon layer, wherein the second reactant gas comprises Si₂H₆ and the second dopant source gas comprises B₂H₆ and in the second LPCVD and the second in-situ doping:
providing the second dopant source gas comprises: providing a second initial dopant source gas comprising B₂H₆; providing a second diluent source gas to dilute the first initial dopant source gas, wherein a volume ratio of the second diluent source gas to the second initial dopant source gas is in a range of about 500:1 to about 1000:1, the second diluent source gas comprises N₂, the second initial dopant source gas comprises a second intrinsic dopant source gas comprising B₂H₆ and a second intrinsic diluting source gas comprising N₂, and a molar ratio of the second intrinsic diluting source gas is about 8% to about 1.5% of the second initial dopant source gas; and
the second dopant source gas has a flow rate of about 2000 sccm to about 3000 sccm, the second reactant gas has a flow rate of about 10 sccm to about 300 sccm, a chamber pressure is about 300 mTorr to about 500 mTorr, and a reaction temperature is about 500 degrees Celsius to about 550 degrees Celsius.

15. The method of claim 14, wherein the memory cell circuit comprises a three-dimensional NAND memory cell circuit and a type of the memory cell circuit is opposite of the dopant polarity of the each of the plurality of doped layers.

16. The method of claim 15, wherein conductively connecting the control circuit and the memory cell circuit comprises forming a metal contact via connecting the control circuit and the memory cell circuit, the metal via being through the memory cell circuit, the plurality of doped layers, and the control circuit.

17. A three-dimensional memory, comprising
a bottom substrate;
a control circuit over the bottom substrate;
a plurality of doped layers over the bottom substrate;
a memory cell circuit over the plurality of doped layers; and
a metal contact via conductively connecting the control circuit and the memory cell circuit, wherein:
the plurality of doped layers has a total thickness in a thickness range such that a top surface of the plurality of doped layers is substantially flat and a doping concentration in each of the plurality of doped layers is substantially uniform along a direction substantially perpendicular to the top surface of the plurality of doped layers.

18. The memory of claim 17, wherein:
a dopant polarity of the each of the plurality of doped layers is same; and
the doping concentration of one of the plurality of doped layers is lower than a lower adjacent one of the plurality of doped layers along the direction substantially perpendicular to the top surface of the plurality of doped layers.

19. The memory of claim 18, wherein the plurality of doped layers comprises a first doped layer over the substrate and a second doped layer over the first doped layer, and wherein the doping concentration of the first doped layer is higher than the doping concentration of the second doped layer.

20. The memory of claim 19, wherein:
the doping concentration of the first doped layer is about 50 to about 200 times of the doping concentration of the second doped layer;
the doping concentration of the first doped layer is in a range of about 1E18 atoms/cm³ to about 2E18 atoms/cm³; and the doping concentration of the second doped layer is in a range of about 1E16 atoms/cm³ to about 3E16 atoms/cm³;
the thickness range is about 200 nm to about 1000 nm; and
the total thickness is about 300 nm.
